(19) United States
(12) Patent Application Publication
(10) Pub. No.: US 2007/0148889 A1
(43) Pub. Date: Jun. 28, 2007

(54) Method for manufacturing a bipolar transisstor

(75) Inventors: Jin Son Kim, Anyang-si (KR); Seok Yong Ko, Boocheon-si (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Dongbu Electronics Co., Ltd.

(21) Appl. No.: 11/646,967

(22) Filed: Dec. 27, 2006

(30) Foreign Application Priority Data
Dec. 28, 2005 (KR) 10-2005-0132646

(51) Int. Cl. H01L 21/331

(52) U.S. Cl. 438/309

(57) ABSTRACT

Disclosed is a method for manufacturing a bipolar transistor. The method includes the steps of forming a well area, which is doped with a first conductive type material, on a semiconductor substrate, forming a base area, which is doped with the first conductive type material, by performing an ion implantation process with respect to the well area, forming an emitter area and a collector area, which are doped with a second conductive type material, by performing an ion implantation process with respect to the well area formed with the base area, and forming a silicide layer on an upper part of the semiconductor substrate except for the emitter area and the collector area.

This application claims the benefit of Korean Application No. 10-2005-0132646, filed on Dec. 28, 2005, which is incorporated by reference herein in its entirety.

### BACKGROUND OF THE INVENTION

1. Field of the Invention

The present invention relates to a method for manufacturing a semiconductor device. More specifically, the present invention relates to a method for manufacturing a bipolar transistor.

2. Description of the Related Art

FIGS. 1A to 1C are sectional views showing a method for forming a conventional bipolar transistor.

First, as shown in FIG. 1A, an ion implantation process is performed with respect to a P type substrate 10 formed with predetermined devices, thereby forming an N type well 12, and a shallow trench isolation (STI) process is performed with respect to the substrate 10, thereby forming an isolation layer 14.

Next, as shown in FIG. 1B, a photoresist pattern (not shown) for defining an emitter area and a collector area is formed on a predetermined area of the semiconductor substrate formed with the isolation layer 14, and P type ions are implanted into the semiconductor substrate by using the photoresist pattern as a mask, thereby forming an emitter area 15c and a collector area 15a. Thereafter, the photoresist pattern is removed.

Last, as shown in FIG. 1C, a photoresist pattern (not shown) for forming a base area is formed at a predetermined area of the substrate formed with the emitter area 15c and the collector area 15a, and N type ions are implanted into the semiconductor substrate by using the photoresist pattern as a mask, thereby forming a base area 15b. Thereafter, the photoresist pattern is removed. Next, a silicide process is performed with respect to the entire surface of the semiconductor substrate 10, thereby forming a silicide layer 18.

Meanwhile, a bipolar transistor having the structure is referred to as a vertical PNP bipolar transistor. Such a structure of the vertical PNP bipolar transistor has a vertical flow of a current passing from an emitter area (N type) to a substrate (P type), which is a collector area, through a base area, which is a well (N type).

However, in the structure of the vertical bipolar transistor having the vertical current flow, since the depth of the N type well serves as the width of the base area, the ratio of a base current to a collector current, which is a current gain of the bipolar transistor, is not high. In other words, since the vertical depth of the N type well is used as the width of the base area, current loss may occur due to the wide width of the base area, so that a collector current becomes small. Accordingly, the ratio of a base current to a collector current, which is a current gain of a bipolar transistor, is not high.

### SUMMARY OF THE INVENTION

The present invention has been made to solve the above problem, and therefore, it is an object of the present invention to provide a method for manufacturing a bipolar transistor having a high current gain.

In order to accomplish the object, there is provided a method for manufacturing a bipolar transistor, the method including the steps of forming a well area, which is doped with a first conductive type material, on a semiconductor substrate, forming a base area, which is doped with the first conductive type material, by performing an ion implantation process with respect to the well area, forming an emitter area and a collector area, which are doped with a second conductive type material, by performing an ion implantation process with respect to the well area formed with the base area, and forming a silicide layer on an upper part of the semiconductor substrate except for the emitter area and the collector area.

Preferably, the first conductive type material includes a P type material, and the second conductive type material includes an N type material, and a predetermined area between the emitter area and the collector area serves as the base area.

### BRIEF DESCRIPTION OF DRAWINGS

FIG. 1 is a sectional view showing a conventional bipolar transistor;

FIG. 2 is a graph showing a current gain of a conventional vertical bipolar transistor;

FIGS. 3A to 3E are sectional views showing a method for manufacturing a bipolar transistor according to the present invention; and

FIG. 4 is a graph showing a current gain of a lateral bipolar transistor according to the present invention.

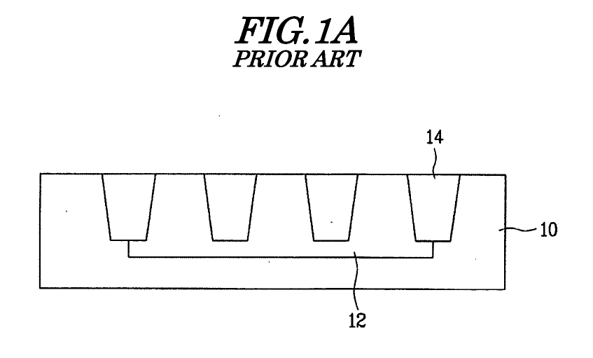

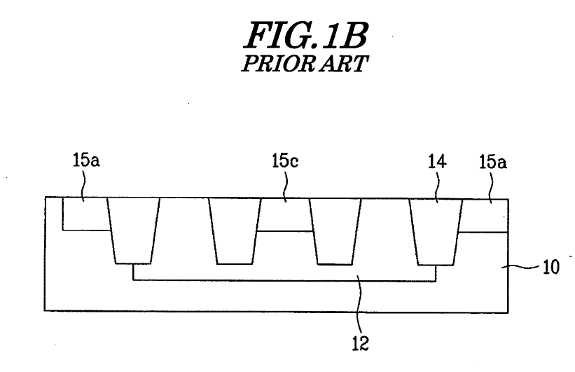

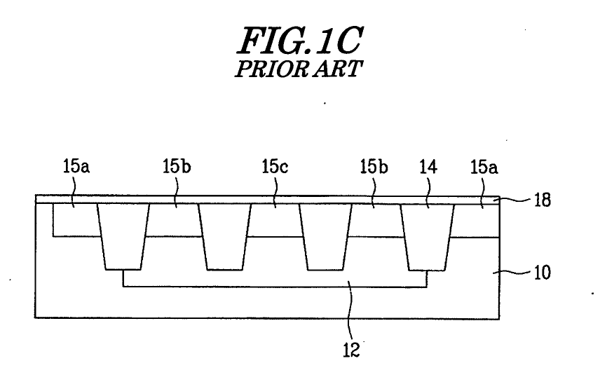

### DETAILED DESCRIPTION OF THE INVENTION

Hereinafter, a preferred embodiment of the present invention will be described with reference to accompanying drawings. The embodiment does not limit the scope of the present invention, but is for illustrative purposes only.

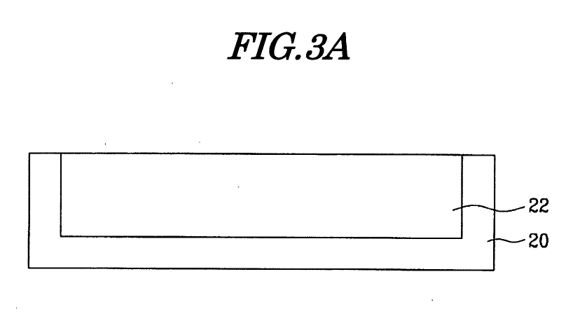

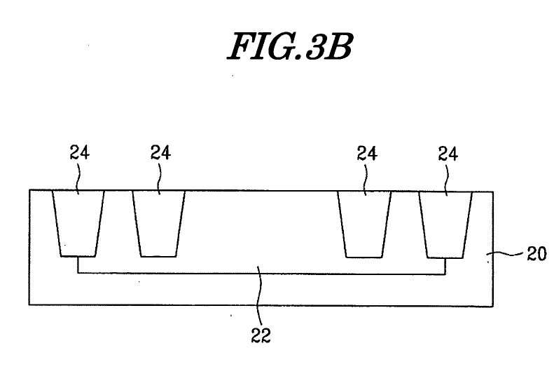

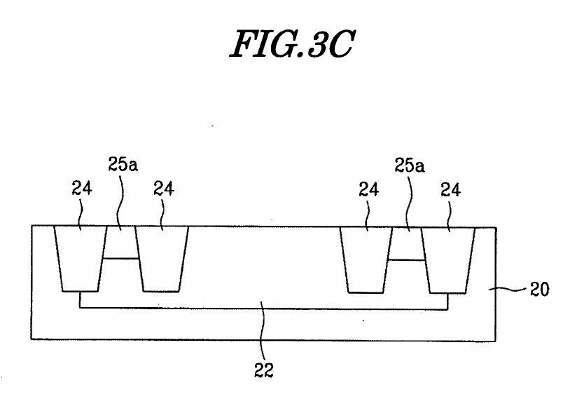

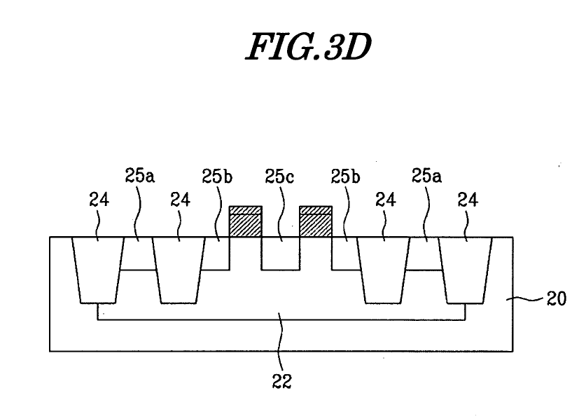

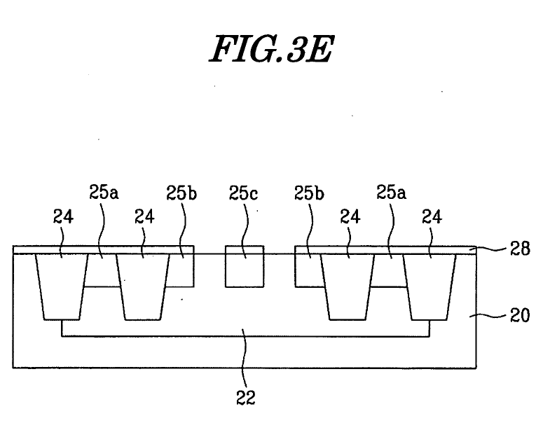

FIGS. 3A to 3E are sectional views showing a method for forming a bipolar transistor according to the present invention.

As shown in FIG. 3A, an N type well 22 is formed on a P type substrate 20, which is formed with predetermined devices, through an ion implantation process.

Thereafter, as shown in FIG. 3B, a shallow trench isolation (STI) process is performed with respect to the substrate, thereby forming an isolation layer 24. Hereinafter, a process of forming the isolation layer will be described in more detail. First, a pad layer is formed on the semiconductor substrate, and then a photolithography process is performed with respect to the pad layer by using an isolation mask, thereby etching the semiconductor substrate to a predetermined depth and patterning the pad layer so as to form a trench. Thereafter, an insulating layer for filling the trench is formed only in the trench, and the pad layer is removed, thereby completely performing the process for forming the isolation layer.

Next, as shown in FIG. 3C, a photoresist pattern (not shown) for defining a base area is formed on a predetermined area of the semiconductor substrate formed with the isolation layer 24, and N type ions are implanted into the semiconductor substrate by using the photoresist pattern as a mask, thereby forming a base area 25a. Thereafter, the photoresist pattern is removed.

Subsequently, as shown in FIG. 3D, a photoresist pattern 26 for defining an emitter area and a collector area is formed on a predetermined area of the substrate formed with the base area 25a, and P type ions are implanted into the semiconductor substrate by using the photoresist pattern 26 as a mask, thereby forming an emitter area 25c and a collector area 25b.

The photoresist pattern 26 allows P type ions to be implanted only into a predetermine area of a well area 22 in which an emitter area and a collector area are defined later.

In other words, there remains an N well area, in which ions are not implanted, between the emitter area 25c and the collector area 25b.

Last, as shown in FIG. 3E, a silicide process is performed with respect to an entire surface of the semiconductor substrate 20 formed with the photoresist pattern 26, thereby forming a silicide layer 28. Thereafter, the photoresist pattern 26 is removed.

Accordingly, the silicide layer 28 is not formed on an upper part of the semiconductor substrate 20 formed between the emitter area 25c and the collector area 25b, such that the upper part of the semiconductor substrate 20 may serve as a base area of a bipolar transistor having a lateral current flow. In addition, the N type ions and the P type ions are not implanted into the upper part of the semiconductor substrate 20, so the well area 22 remains as it is.

Meanwhile, the bipolar transistor according to the present invention is a lateral bipolar transistor and has a current flow from the emitter area 25c to the collector area 25b through the N type well 22 (used as the base area). Accordingly, the bipolar transistor having a vertical current flow has a relatively high gain even in an emitter area having the size of a conventional emitter area because a current passes through a base area having a narrow width.

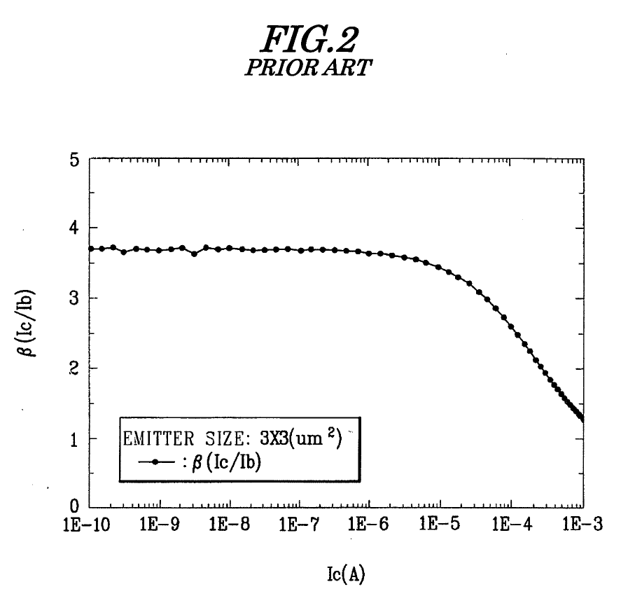

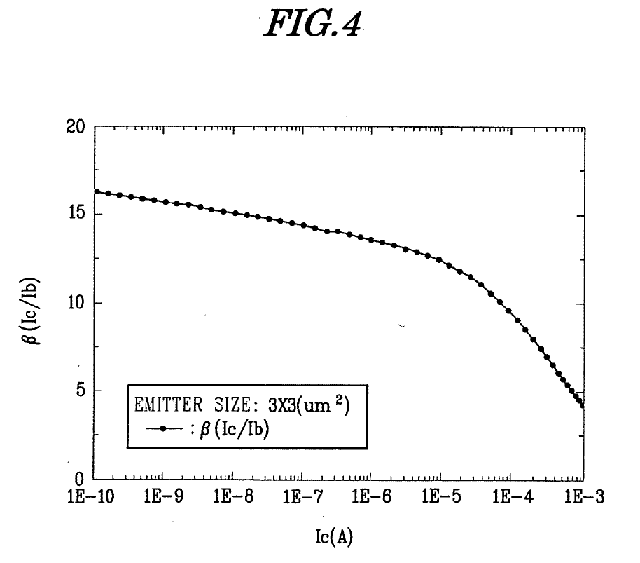

FIG. 2 is a graph showing a current gain of a conventional vertical bipolar transistor, and FIG. 4 is a graph showing a current gain of a lateral bipolar transistor according to the present invention. When comparing the graph shown in FIG. 2 and the graph shown in FIG. 4, it can be recognized that a current gain of the lateral bipolar transistor is higher than a current gain of the vertical transistor.

Accordingly, the lateral bipolar transistor according to the present invention has a higher current gain.

As described above, according to the present invention, a lateral bipolar transistor having a high current gain can be obtained.

What is claimed:

1. A method for manufacturing a bipolar transistor, the method comprising the steps of:
forming a well area doped with a first conductive type material on a semiconductor substrate;
forming a base area doped with the first conductive type material by performing an ion implantation process with respect to the well area;
forming an emitter area and a collector area, each doped with a second conductive type material, by performing an ion implantation process with respect to the well area and the base area; and
forming a silicide layer on an upper part of the semiconductor substrate except on the emitter area and the collector area.

2. The method as claimed in claim 1, wherein the first conductive type material includes a P type material, and the second conductive type material includes an N type material.

3. The method as clamed in claim 1, wherein the base area is in a predetermined area between the emitter area and the collector area.

4. A method for manufacturing a bipolar transistor, the method comprising the steps of:
implanting a first conductive type dopant into an area of a semiconductor substrate to form a well;
implanting a higher dose of the first conductive type dopant in a predetermined region of the well to form a base;
implanting a second conductive type dopant into predetermined areas of the well to form an emitter and a collector; and
forming a silicide layer on the base.

5. The method as claimed in claim 4, wherein the first conductive type material includes a P type material, and the second conductive type material includes an N type material.

6. The method as clamed in claim 4, wherein the base is in a predetermined area between the emitter area and the collector area.

7. The method as clamed in claim 4, further comprising forming a plurality of isolation structures in the substrate.

8. The method as clamed in claim 7, wherein, in a cross section of the bipolar transistor, the base is between first and second isolation structures, and the emitter and collector are between second and third isolation structures.

9. The method as clamed in claim 4, wherein the base is in a predetermined area between the emitter area and the collector area.

10. The method as clamed in claim 4, further comprising forming a first patterned photoresist prior forming the well.

11. The method as clamed in claim 4, further comprising forming a second patterned photoresist with an opening over the predetermined region of the well prior to implanting the first conductive type dopant to form the base.

12. The method as clamed in claim 6, further comprising forming a third patterned photoresist masking the base prior to implanting the second conductive type dopant to form the emitter and the collector.

13. A bipolar transistor, comprising:
a well in a semiconductor substrate, doped with first conductive type ions;
a base area in the well, doped with a higher concentration of the first conductive type ions;
an emitter and a collector in the well, each doped with second conductive type ions; and
a silicide layer on the emitter and the collector.

14. The transistor as claimed in claim 13, wherein the first conductive type ions include P type ions, and the second conductive type ions include N type ions.

15. The transistor as clamed in claim 13, wherein the base area is in a predetermined area between the emitter and the collector.

16. The transistor as clamed in claim 13, further comprising a plurality of isolation structures in the substrate.

17. The transistor as clamed in claim 16, wherein the base is between first and second isolation structures, and the emitter and collector are between second and third isolation structures, in a cross section of the transistor.
